(19) United States
(12) Patent Application Publication
(10) Pub. No.: US 2010/0066355 A1
(43) Pub. Date: Mar. 18, 2010

(54) PROCESS MEASURING DEVICE

(76) Inventors: Peter Krause, Karlsruhe (DE); Michael Ludwig, Karlsruhe (DE)

Correspondence Address: SIEMENS CORPORATION;INTELLECTUAL PROPERTY DEPARTMENT, 170 WOOD AVENUE SOUTH, ISELIN, NJ, 08830, US

(21) Appl. No.: 12/556,921

(22) Filed: Sep. 10, 2009

(30) Foreign Application Priority Data
Sep. 12, 2008 (EP) 08016134.2

(51) Int. Cl. G01R 33/12; G01N 27/00; G01N 7/00

(52) U.S. Cl. 324/228; 324/71.1; 73/23.2

(57) ABSTRACT

A process measuring device configured to identify malfunctions due to hardware and/or software errors is provided. The process measuring device includes a measuring unit for converting a non-electric variable to an electric variable with a modulation facility modulating the conversion, a signal processing device for processing the electric variable, or an electric raw signal obtained from the electric variable by signal preprocessing, by a signal processing software to produce a measured value, and means for obtaining a test signal corresponding to the modulation. Further, the device includes means in the form of the signal processing device for processing the test signal by the signal processing software to produce a diagnosis value and means for monitoring the signal processing device by comparing the diagnosis value with an expected value.

### CROSS REFERENCE TO RELATED APPLICATIONS

This application claims priority of European Patent Office Application No. 08016134.2 EP filed Sep. 12, 2008, which is incorporated by reference herein in its entirety.

### FIELD OF INVENTION

The invention relates to a process measuring device.

### BACKGROUND OF INVENTION

A plurality of different process measuring devices are used in process automation and process engineering to measure physical or chemical variables. Such variables include for example pressure, throughflow, temperature, concentrations of certain gas or fluid components in gas and/or fluid mixtures, pH value of fluids and many more. Each process measuring device contains a measuring unit, in which the respective non-electric variable is converted to an electric variable in accordance with an appropriate measuring principle.

Thus in the case of a temperature sensor the temperature dependency of an electrical resistance is generally used to generate a temperature-proportional voltage or current signal.

When measuring the throughflow of an electrically conductive fluid by means of ,a magnetically inductive flow meter, the current-dependent deflection of charge carriers of the fluid in a magnetic field is captured as the electrical voltage between two measuring electrodes.

As different gases have different specific thermal conductivities, the concentration of a certain gas component in a gas mixture can be detected by means of a thermal conductivity detector. In this process the cooling of a heating filament around which the gas mixture flows is captured, to which end the change in its resistance is measured as in the case of a temperature sensor.

Other gas analyzers, such as laser spectrometers or non-dispersive infrared (NDIR) gas analyzers for example, detect the wavelength-specific radiation absorption in gases.

In the case of a paramagnetic oxygen sensor oxygen molecules are moved in the direction of higher field strength in a non-homogeneous magnetic field due to their paramagnetism. If a measuring gas and a reference gas with a different oxygen content are brought together in such a magnetic field, a pressure difference results between them, which is detected.

To suppress interference and offset, the conversion of the non-electric variable to the electric variable is generally modulated, in that, staying with the above-mentioned examples, the resistor of the temperature sensor or the heating filament of the thermal conductivity detector is fed an alternating current voltage, in the case of the magnetically inductive flow meter and the paramagnetic oxygen sensor a pulsed or alternating magnetic field is generated, in the case of the laser spectrometer the laser is modulated and in the case of the NDIR gas analyzer an aperture wheel is used for periodic radiation interruption.

Depending on the nature of the electric variable produced from the physical or chemical variable, it is fed immediately or after signal preprocessing, such as filtering and/or amplifying, as a raw signal to a signal processing facility, which processes the electric variable or raw signal using signal processing software to produce a measured value. Measured value here should be seen as synonymous with measured value sequence or measurement signal; in other words the measured value changes with the captured non-electric variable.

Hardware and/or software errors can cause signal processing to produce incorrect measured values. Hardware errors can occur sporadically, while software errors are generally systematic by nature.

### SUMMARY OF INVENTION

An object of the invention is to specify measures to allow such errors to be identified.

The object is achieved by the process measuring device as claimed in the independent claim.

Advantageous developments of the inventive process measuring device can be found in the dependent claims.

The subject matter of the invention is therefore a process measuring device
with a measuring unit for converting a non-electric variable to an electric variable, comprising a modulation facility modulating the conversion,
with a signal processing facility for processing the electric variable or an electric raw signal obtained therefrom by signal preprocessing by means of signal processing software to produce a measured value,
with means for obtaining a test signal corresponding to the modulation,
with means in the form of the signal processing facility for processing the test signal by means of the signal processing software to produce a diagnosis value and
with means for monitoring the signal processing facility by comparing the diagnosis value with an expected value.

The test signal obtained from modulation during conversion of the non-electric variable to the electric variable has identical or at least similar signal characteristics to the electric variable or raw signal to be processed, so that greater test coverage is achieved than would be the case with a test signal generated by a separate signal generator. Since the modulation is predetermined and therefore, unlike the raw signal for example, the test signal derived therefrom is known, an expected value for the result (i.e. the above-mentioned diagnosis value) of error-free signal processing can be predetermined or determined during calibration of the process measuring device. As long as the diagnosis value lies within a tolerance range around the expected value, signal processing can be considered to be error-free. Otherwise an error or alarm report is generated and the measured value is adjusted for example in a safety-oriented manner.

It is possible for the signal processing software to process the test signal in measurement breaks instead of the electric variable or raw signal. The signal processing software is preferably present in a duplicate embodiment, so that the electric variable or the raw signal and the test signal can be processed in parallel.

If the process measuring device and/or its measuring unit is a gas analyzer operating according to the principle of radiation absorption with an intensity and/or wavelength-modulated radiation source, the means for obtaining the test signal comprise a monitor detector capturing the modulated radiation or provide the modulation signal for the radiation source as the test signal. Such a monitor detector is already present in many gas analyzers to measure the radiation intensity produced and to detect reductions in intensity due to ageing of the radiation source or contamination. The modulation signal can be the actuation signal of a laser diode for example.

In the case of an NDIR gas analyzer with a radiation-modulating aperture wheel the test signal is preferably captured by means of a light barrier, which is generally present anyway to monitor the rotation of the aperture wheel.

In the case of a gas analyzer operating according to the paramagnetic alternating pressure method or a magnetically inductive flow meter, each of which comprises an electromagnet generating a magnetic field with alternating flux strength, the test signal is preferably supplied by a magnetic field sensor monitoring the magnetic field or the coil current of the electromagnet is used as the test signal.

In the case of a temperature sensor or a thermal conductivity detector (WLD) the temperature-dependent measuring resistor (the heating filament of the WLD) is supplied with an alternating current or synonymously an alternating current voltage, with the alternating current being used as the test signal.

### BRIEF DESCRIPTION OF THE DRAWINGS

The invention is described in more detail below with reference to the figures in the drawing, in which by way of example:

FIG. 1 shows a block diagram of the inventive process measuring device,

FIG. 2 shows a measuring unit in the foam of an NDIR gas analyzer,

FIG. 3 shows a measuring unit in the form of a gas analyzer operating according to the paramagnetic alternating pressure method,

FIG. 4 shows a measuring unit in the form of a magnetically inductive flow meter and

FIG. 5 shows a measuring unit 1 in the form of a gas analyzer with an intensity and/or wavelength-modulated radiation source.

### DETAILED DESCRIPTION OF INVENTION

The process measuring device shown in FIG. 1 has a measuring unit 1, which converts a non-electric, for example a physical or chemical, variable 2 to an electric variable 3. The conversion is modulated by means of a modulation facility 4 influencing the measuring unit 1. The modulation facility 4 can also be part of the measuring unit 1. In a facility 5 the electric variable 3 is used to obtain a raw signal 6 by signal preprocessing, for example filtering, amplifying or delta-sigma modulation. Depending on the nature of the electric variable 3 it may also be possible to dispense with signal preprocessing. The raw signal 6 or optionally the electric variable 3 is processed in a signal processing facility 7 using signal processing software 8 to produce a measured value 9, which is then displayed or communicated to other devices within a process automation system.

Modulation of the conversion of the non-electric variable 2 to the electric variable 3 produces a test signal 10, which is also supplied to the signal processing facility 7 and is processed there by the same signal processing software to produce a diagnosis value 11. To this end in the example shown the signal processing software is present in a duplicate embodiment 8, 8′, so that the raw signal 6 and the test signal 10 are processed in parallel. Otherwise the signal processing software 8 processes the test signal 10 in measurement breaks instead of the raw signal 6. A comparison facility 12 compares the diagnosis value 11 with an expected value 13, which is stored in a storage unit 14 and has been previously calculated or has been determined during calibration of the intact process measuring device. If the diagnosis value 11 deviates by more than a permitted measure from the expected value 13, an error report 15 is generated and the measured value 9 is set at a safety-oriented value by means of a facility 16 for example.

It is important for the test signal 10 that it is obtained from modulation of the conversion of the non-electric variable 2 to the electric variable 3 and thus has identical or at least similar signal characteristics to the modulated electric variable 3 or the raw signal 6. This allows a high level of test coverage to be achieved compared with the generation of a test signal by means of a test signal generator and an additional error source is avoided.

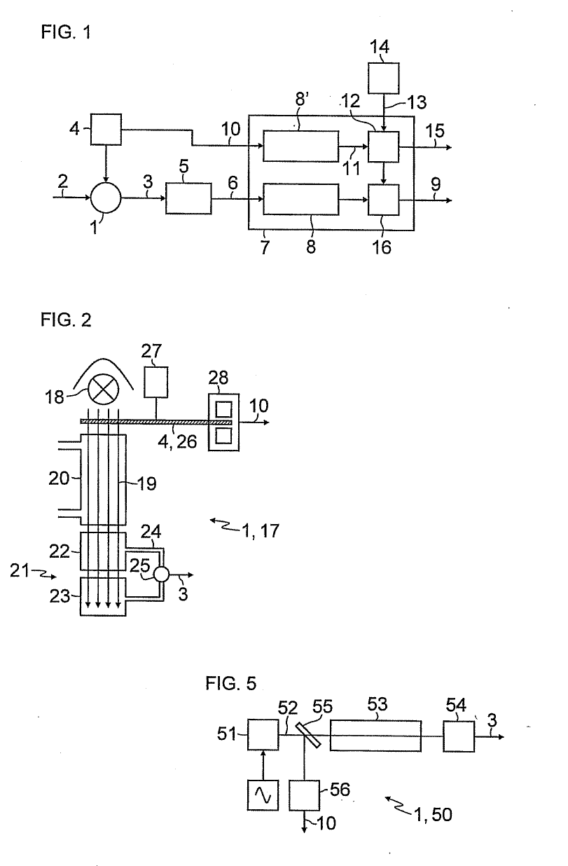

FIG. 2 shows an example of a measuring unit 1 in the form of an NDIR gas analyzer 17. This contains an infrared radiation source 18, the radiation 19 of which is directed into a measuring vessel 20. The measuring vessel 20 contains a gas mixture with a gas component to be detected. An opto-pneumatic detector 21 is arranged behind the measuring vessel 20, consisting in the known manner of two radiation-permeable chambers 22 and 23, which are arranged one behind the other and are filled with the gas component, being connected by way of a line 24 to a pressure or flow-sensitive sensor 25, which is arranged therein and generates the electric variable 3 as the sensor signal.

The infrared radiation 19 is modulated by means of an aperture wheel 26 forming the modulation facility 4, which is driven by a motor 27 and interrupts the beam path intermittently. A light barrier 28 is present to monitor the rotation of the aperture wheel 26, its monitoring signal being used as the test signal 10.

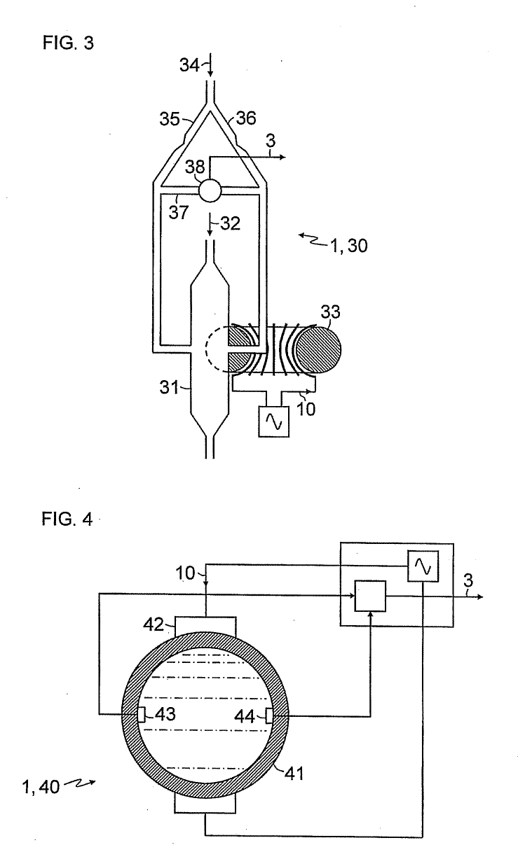

FIG. 3 shows an example of a measuring unit 1 in the form of a gas analyzer 30 operating according to the paramagnetic alternating pressure method. The measuring unit 1 has a measuring chamber 31, through which a measuring gas 32 flows, the oxygen content of which is to be determined. Part of the measuring chamber 31 lies between the pole shoes of an electromagnet 33 with an alternating current supply in the magnetic field generated by it. A comparison gas 34 required to achieve the measuring effect is supplied to the measuring chamber 31 through two identically shaped channels 35 and 36, with one of the two comparison gas flows meeting the measuring gas 32 in the region of the magnetic field. Since oxygen molecules are moved in the direction of higher field strength in the magnetic field due to their paramagnetic characteristics, an alternating pressure difference results between the comparison gas flows in the channels 35 and 36. This brings about a flow in a connecting channel 37 between the two channels 35 and 36, which is captured by means of a micro-flow sensor 38 and converted to the electric variable 1.

The coil current of the electromagnet 33 is used as the test signal 10 here. Alternatively the test signal can be generated by means of a magnetic field sensor provided to monitor the electromagnet 33.

FIG. 4 shows an example of a measuring unit 1 in the form of a magnetically inductive flow meter 40. This has a generally non-conducting measuring tube 41 or one which is non-conducting on the inside at least, through which an electrically conductive medium flows in the direction of the measuring tube axis. An electromagnet 42 generates a pulsed or alternating-direction magnetic field oriented perpendicular to the flow direction of the medium between two diametrically arranged pole shoes, under the influence of which magnetic field charge carriers in the medium migrate according to their polarity toward one or the other of two measuring electrodes 43 and 44 arranged opposite one another in the measuring tube 41. The electric voltage building up between the measuring electrodes 43 and 44 is proportional to the mean flow speed of the medium over the cross-section of the measuring tube 41 and forms the electric variable 3.

The coil current of the electromagnet 42 is used as the test signal 10 here too. Alternatively the test signal can be generated by means of a magnetic field sensor provided to monitor the electromagnet 42.

FIG. 5 finally shows an example of a measuring unit 1 in the form of a gas analyzer 50 with an intensity and/or wavelength-modulated radiation source 51. After passing through a measuring vessel 53 filled with a measuring gas, the generated radiation 52 meets a measuring detector 54, the output signal of which forms the electric variable 3.

To monitor the radiation source 51, a beam splitter 55 is used to deflect part of the generated radiation 52 onto a monitor detector 56, the monitor signal of which is used here as the test signal 10. Alternatively the actuation signal modulating the radiation source 51 can also be used as the test signal 10.

1.-8. (canceled)

9. A process measuring device, comprising:
a measuring unit for converting a non-electric variable to an electric variable, the measuring unit including a modulation facility modulating the conversion;
a signal processing device for processing the electric variable by a signal processing software to produce a measured value;
means for obtaining a test signal corresponding to the modulation;
means in the form of the signal processing device for processing the test signal by the signal processing software to produce a diagnosis value; and
means for monitoring the signal processing device by comparing the diagnosis value with an expected value.

10. The process measuring device as claimed in claim 9, wherein an electric raw signal is processed instead of the electric variable, the electric raw signal being obtained from the electric variable by signal preprocessing.

11. The process measuring device as claimed in claim 9, wherein the signal processing software temporarily processes the test signal instead of the electric variable.

12. The process measuring device as claimed in claim 10, wherein the signal processing software temporarily processes the test signal instead of the electric raw signal.

13. The process measuring device as claimed in claim 9, wherein the signal processing software is present in a duplicate embodiment and processes the electric variable and the test signal in parallel.

14. The process measuring device as claimed in claim 10, wherein the signal processing software is present in a duplicate embodiment and processes the electric raw signal and the test signal in parallel.

15. The process measuring device as claimed in claim 9, wherein
the measuring unit comprises a gas analyzer operating according to a principle of radiation absorption with an intensity and/or wavelength-modulated radiation source and
the means for obtaining the test signal comprise a monitor detector capturing the modulated radiation or provide the modulation signal for the radiation source as the test signal.

16. The process measuring device as claimed in claim 10, wherein
the measuring unit comprises a gas analyzer operating according to a principle of radiation absorption with an intensity and/or wavelength-modulated radiation source and
the means for obtaining the test signal comprise a monitor detector capturing the modulated radiation or provide the modulation signal for the radiation source as the test signal.

17. The process measuring device as claimed in claims 9, wherein
the measuring unit comprises a non-dispersive infrared gas analyzer with a radiation-modulating aperture wheel and
the means for obtaining the test signal comprise a light barrier monitoring the rotation of the aperture wheel.

18. The process measuring device as claimed in claims 10, wherein
the measuring unit comprises a non-dispersive infrared gas analyzer with a radiation-modulating aperture wheel and
the means for obtaining the test signal comprise a light barrier monitoring the rotation of the aperture wheel.

19. The process measuring device as claimed in claim 9, wherein
the measuring unit comprises a gas analyzer operating according to the paramagnetic alternating pressure method with an electromagnet generating a magnetic field with alternating flux strength and
the means for obtaining the test signal comprise a magnetic field sensor monitoring the generated magnetic field or provide the coil current of the electromagnet as the test signal.

20. The process measuring device as claimed in claim 10, wherein
the measuring unit comprises a gas analyzer operating according to the paramagnetic alternating pressure method with an electromagnet generating a magnetic field with alternating flux strength and
the means for obtaining the test signal comprise a magnetic field sensor monitoring the generated magnetic field or provide the coil current of the electromagnet as the test signal.

21. The process measuring device as claimed in claim 9, wherein
the measuring unit comprises a magnetically inductive flow meter with an electromagnet generating a magnetic field with alternating flux strength and
the means for obtaining the test signal comprise a magnetic field sensor monitoring the generated magnetic field or provide the coil current of the electromagnet as the test signal.

22. The process measuring device as claimed in claim 10, wherein
the measuring unit comprises a magnetically inductive flow meter with an electromagnet generating a magnetic field with alternating flux strength and
the means for obtaining the test signal comprise a magnetic field sensor monitoring the generated magnetic field or provide the coil current of the electromagnet as the test signal.

23. The process measuring device as claimed in claims 9, wherein
the measuring unit contains a temperature-dependent measuring resistor supplied with an alternating current and
the means for obtaining the test signal provide the alternating current as the test signal.

24. The process measuring device as claimed in claims 10, wherein
the measuring unit contains a temperature-dependent measuring resistor supplied with an alternating current and
the means for obtaining the test signal provide the alternating current as the test signal.
